(19) United States
(12) Patent Application Publication
(10) Pub. No.: US 2016/0237549 A1
(43) Pub. Date: Aug. 18, 2016

(54) MANUFACTURING METHOD OF METALLIC FILM AND OUTSIDE DOOR HANDLE FOR VEHICLE

(71) Applicant: AISIN SEIKI KABUSHIKI KAISHA, Kariya-shi, Aichi (JP)

(72) Inventors: Takashi HARA, Obu-shi (JP); Kazuki MIZUTANI, Miyoshi-shi (JP)

(73) Assignee: AISIN SEIKI KABUSHIKI KAISHA, Kariya-shi, Aichi (JP)

(21) Appl. No.: 15/026,813

(22) PCT Filed: Sep. 19, 2014
(86) PCT No.: PCT/JP2014/074866

§ 371 Date: Apr. 1, 2016

(30) Foreign Application Priority Data
Oct. 2, 2013 (JP) 2013-206949

(51) Int. Cl. C23C 14/34; C23C 14/58; E05B 1/00; E05F 15/77; E05B 81/64; E05B 81/78; B60J 5/04; E05F 15/46; C23C 14/20; E05B 79/06

(52) U.S. Cl. CPC C23C 14/34; C23C 14/205; C23C 14/5886; E05B 1/0053; E05B 79/06; E05B 81/64; E05B 81/78; B60J 5/0493; E05F 15/46; E05F 15/77

(57) ABSTRACT

A manufacturing method of a metallic film being formed on a surface of a non-electric conductive base material, the manufacturing method includes a first deposition process depositing a first chrome film being made of chrome on the surface of the base material at a first deposition speed by sputtering, a second deposition process depositing a second chrome film being made of chrome on a surface of the first chrome film at a second deposition speed that is higher than the first deposition speed by sputtering, and a crack forming process forming a crack within the first chrome film and within the second chrome film by an application of a stress to the first chrome film and to the second chrome film.

### TECHNICAL FIELD

The present invention relates to a manufacturing method of a metallic film and an outside door handle for a vehicle. The present invention particularly relates to the manufacturing method of the metallic film that includes a great radio wave permeability and great electrical insulation properties and that includes metallic luster. The present invention further particularly relates to the outside door handle for the vehicle in which the metallic film is formed on a surface of a handle body.

### BACKGROUND ART

In recent years, a door handle for a smart entry system is often used for an outside door handle for a vehicle. The door handle for the door handle for the smart entry system includes a handle body that is made from a non-electric conductive resin base material and that is operated when a user opens a door. The door handle for the door handle for the smart entry system further includes an antenna that is contained in the handle body and that receives signals sent from a smart key. Furthermore, a film (hereinafter referred to as a metallic film) having metallic luster is formed on an outer surface of the handle body (the base material) to enhance designability.

The door handle for the door handle for the smart entry system is required to include a feature that precisely receives the signals sent from the smart key, and a feature that precisely detects a change in capacitance caused by a touch of a human body to a predetermined position of the handle for the door handle for the smart entry system in order to open and close the door in a case where the user touches the predetermined position of the door handle for the smart entry system. The metallic film formed on the outer surface of the handle body is required to include a high radio wave permeability in order to precisely receive the radio wave sent from the smart key. Along with that, the metallic film formed on the outer surface of the handle body is required to include high electrical insulation properties in order to prevent an incorrect operation in a case where the user touches a position other than the predetermined position of the door handle for the smart entry system.

Patent document 1 discloses a manufacturing method of a metallic film, the manufacturing method including a deposition process depositing a chrome film that serves as a metallic film on a surface of a resin base material, and a heating process heating the chrome film together with the resin base material. Patent document 2 discloses a manufacturing method of a metallic film, the manufacturing method including a forming process forming an aluminum film and a chrome film on a surface of a non-electric conductive polycarbonate resin base material by a dry plating process (for example, sputtering), and a heating process heating the aluminum film and the chrome film together with the polycarbonate resin base material. According to each of the manufacturing methods of the metallic films disclosed in these Patent documents, cracks are formed within the metallic film by an external stress and an internal stress, the external stress caused by a volume expansion resulted from the heating of the resin base material, the internal stress caused by the heating and an oxidization of the metallic film. Because the cracks are formed and the metallic film is fragmented, electrical insulation properties and the radio wave permeability are enhanced.

### DOCUMENT OF PRIOR ART

### Patent Document

Patent document 1: JP2012-153910A

Patent document 2: JP2009-286082A

### OVERVIEW OF INVENTION

### Problem to be Solved by Invention

In a case where the metallic film is deposited on the surface of the base material by sputtering, the internal stress within the metallic film is also generated by an accumulation of, for example, thermal energy of metal particles that are deposited on the surface of the base material during the deposition process. The internal stress generated within the metallic film changes in accordance with the deposition condition. In a case where the internal stress is too high, adhesive properties of the metallic film being deposited on the surface of the base material are impaired (the adhesive strength is decreased). Along with that, a specularity of the film after the cracks are formed is decreased. The metallic film may be separated from the resin base material, and the metallic appearance having the enhanced specularity as a wet plating film cannot be provided.

Furthermore, in a case where two types of metals (aluminum and chrome) are used as a source of the metallic film as disclosed in Patent document 2, a material cost is high. In addition, because plural sputtering sources are required, a device is expensive. Moreover, a design surface is configured by a surface of the metallic film that is deposited by the use of the two types of metal (aluminum and chrome) as the source of the metallic film by a method disclosed in Patent document 2, the surface where an aluminum metal is deposited. Thus, when comparing to a chrome plating film for decoration (a decorative chrome plating film) that is deposited by a wet plating process and that includes the metallic luster, coloration differs because of the difference of the metal types of the design surface. Thus, in a case where a component having a surface that is coated with the metallic film manufactured by the method disclosed in Patent document 2 is applied to one of many automobile components that include the decorative chrome plating films, because the coloration of the component differs from a peripheral component being coated with the decorative chrome plating film, an uniformity is impaired. Specifically, a surface of a component that is positioned in the vicinity of the outside door handle for the vehicle includes the decorative chrome plating film that is deposited by the wet plating process. Thus, in a case where the metallic film is formed on the surface of the handle body of the outside door handle for the vehicle by the method disclosed in Patent document 2, the brightness of the handle body of the outside door handle for the vehicle is difficult to be matched with the brightness of the peripheral component. As a result, the uniformity may be impaired due to the difference in brightness.

The object of the present invention is, to provide a manufacturing method of a metallic film that inhibits an impairment of adhesive properties relative to a base material, that includes a brightness that is close to a brightness of a decorative chrome film and sufficiently enhanced specularity, and that includes enhanced electrical insulation properties and an enhanced radio wave permeability. In addition, the further object of the present invention is to provide an outside door handle for a vehicle in which the metallic film having aforementioned characteristic properties is formed on a surface of a handle body.

### Means for Solving Problem

According to the present invention, a manufacturing method of a metallic film being formed on a surface of a non-electric conductive base material is provided, the manufacturing method includes a first deposition process depositing a first chrome film being made of chrome on the surface of the base material at a first deposition speed by sputtering, a second deposition process depositing a second chrome film being made of chrome on a surface of the first chrome film at a second deposition speed that is higher than the first deposition speed by sputtering, and a crack forming process forming a crack within the first chrome film and within the second chrome film by an application of a stress to the first chrome film and to the second chrome film. In this case, it is favorable that the first deposition speed corresponds to a deposition speed which is low to an extent where the first chrome film includes an adhesive strength which is to an extent where the first chrome film is not removed from the base material, the first deposition speed corresponding to the deposition speed which is low to an extent where the first chrome film has an enhanced specularity, and the second deposition speed corresponds to a deposition speed which is high to an extent where the second chrome film has a brightness that is equal to or greater than a predetermined brightness.

According to the present invention, because the metal being used during the deposition process is chrome only, costs for a film material and for an equipment can be reduced comparing to a case where two or more types of metals are used. In addition, because the first chrome film is deposited on the surface of the base material at the low speed in the first deposition process (the first deposition speed), the internal stress generated within the first chrome film is reduced. That is, the stress is relieved. As a result, the adhesive properties of the base material and the chrome film can be inhibited from being impaired. However, the brightness of the chrome film deposited at a low speed is lower than the brightness of a general decorative chrome plating film being used for a vehicle component, that is, the brightness of the chrome plating film being deposited by a wet plating process. Here, according to the present invention, in the second deposition process, the second chrome film is deposited on a surface of the first chrome film, which is deposited on the surface of the base material in the first deposition process, at a speed (a second deposition speed) higher than a first deposition speed. Thus, the brightness of the surface of the chrome film (the second chrome film) is close to the brightness of the decorative chrome plating film. Accordingly, the brightness of the metallic film manufactured by the manufacturing method according to the present invention and of the decorative chrome plating film can be substantially coincided with each other. Thus, the uniformity between a component formed with the metallic film manufactured by the manufacturing method according to the present invention and a peripheral decorative chrome plating component can be generated.

In addition, because cracks are formed within the first chrome film and within the second chrome film in the crack forming process, electrical insulation properties and a radio wave permeability can be enhanced. Because an internal stress of the first chrome film is small, a diffuse reflection at a surface of the metallic film being manufactured through the crack forming process can be inhibited. Accordingly, the metallic film can include an enhanced specularlity, in particular, the enhanced specularity that is substantially equal to a specularity of the decorative chrome plating film deposited by the wet plating process. As such, according to the present invention, the manufacturing method of the metallic film can be provided, the manufacturing method that inhibits an impairment of an adhesive properties of the metallic film relative to the base material and maintains the adhesive properties favorably, that includes a brightness close to a brightness of the decorative chrome film being deposited by the wet plating process and a sufficient specularity, and that has the enhanced radio wave permeability and the enhanced electrical insulation properties.

It is favorable that the first deposition speed, that is, the deposition speed of the first chrome film corresponds to a deposition speed which is low to an extent where an internal stress generated within the first chrome film is equal to or less than a predetermined internal stress. The deposition speed has a correlation with the internal stress, and the lower the deposition speed is, the smaller the internal stress is. Because the first chrome film is deposited at the low deposition speed so that the internal stress is equal to or less than a predetermined stress, the adhesive properties of the metallic film relative to the base material can be sufficiently inhibited from being impaired and the sufficient specularity can be provided. It is favorable that the aforementioned predetermined internal stress is approximately 3000 MPa. In a case where the internal stress is equal to or less than this degree, the adhesive properties are not affected and the sufficient specularity can be provided on the metallic film after the cracks are formed.

Furthermore, it is favorable that the second deposition speed, that is, the deposition speed of the second chrome film, corresponds to a deposition speed which is high to an extent where the brightness of the second chrome film is equal to a brightness of the decorative chrome plating film. The deposition speed has the correlation with the brightness. The higher the deposition speed is, the higher the brightness is. Thus, because the second chrome film is deposited at the high speed so that the brightness of the second chrome film is equal to the brightness of the decorative chrome plating film deposited by the wet plating process, the brightness of a component that includes a surface being covered with the second chrome film can be matched with the brightness of a peripheral component that is covered with the decorative chrome plating film. Meanwhile, the brightness of the decorative chrome plating film corresponds to approximately 82 to 83 in a case where the brightness of the decorative chrome plating film is expressed by L* of the L*a*b color system. Thus, it is favorable that the second deposition speed is equal to or greater than 80 in a case where the brightness of the second chrome film is expressed by L*.

In this case, it is favorable that the first deposition speed is equal to or less than 0.6 nanometer per second (nm/sec.), and the second deposition speed is equal to or greater than 1.2 nm/sec. In a case where the first deposition speed is equal to or less than 0.6 nm/sec., the internal stress generated within the first chrome film can be sufficiently reduced. Thus, the stress is sufficiently relieved. The impairment of the adhesive properties of the base material and the chrome film due to the internal stress can be sufficiently inhibited. The sufficient specularity can be provided. Thus, the adhesive properties of the base material and the chrome film can be favorably maintained and the malfunction in which, for example, the chrome film is removed can be securely prevented. In a case where the second deposition speed is equal to or greater than 1.2 nm/sec., the brightness of the second chrome film can be sufficiently close to the brightness of the decorative chrome plating film being deposited by the wet plating process. Accordingly, the brightness of the component including the surface covered with the second chrome film can be matched with the brightness of the peripheral component being covered with the decorative chrome plating film.

It is favorable that a total film thickness serving as a sum of the film thickness of the first chrome film deposited in the first deposition process and the film thickness of the second chrome film deposited in the second deposition process is equal to or greater than 30 nm. The brightness of the metallic film further relates to the total film thickness. The brightness of the metallic film in a case where the total film thickness is less than 30 nm is considerably lower than the brightness of the decorative chrome plating film being deposited by the wet plating process. On the other hand, the brightness of the metallic film in a case where the total film thickness is equal to or greater than 30 nm is equal to the brightness of the decorative chrome plating film being deposited by the wet plating process.

In this case, it is favorable that the total film thickness is equal to or greater than 50 nm. In a case where the total film thickness is equal to or greater than 50 nm, the thickness of the second chrome film is thicker than the second chrome film in a case where the total film thickness is less than 50 nm. Thus, the brightness can be further enhanced. In addition, in a case where the total film thickness is equal to or greater than 50 nm, and even in a case where a portion where the film thickness is partially thin due to the variation of the film thickness is formed, it is highly possible that the film thickness of the portion is equal to or greater than 30 nm. Thus, the metallic film can be deposited, the metallic film that includes the brightness in the whole film-coated area sufficiently close to the brightness of the decorative chrome plating film being deposited by the wet plating process.

Furthermore, it is favorable that the film thickness of the second chrome film being deposited in the second deposition process is greater than the film thickness of the first chrome film being deposited in the first deposition process. The deposition speed of the second chrome film is faster than the deposition speed of the first chrome film. Under the condition where the total film thickness is in common, the deposition time required in a case where the second chrome film is thicker than the first chrome film is shorter than the deposition time required in a case where the first chrome film and the second chrome film include the same thickness, and in a case where the second chrome film is thinner than the first chrome film. Thus, the deposition time can be shortened. Accordingly, the productivity can be enhanced. In addition, because the film thickness of the second chrome film is high, the brightness can be further enhanced. In this case, it is favorable that a ratio R (T2/T1) of a film thickness T2 of the second chrome film relative to a film thickness T1 of the first chrome film is equal to or greater than 5 and is equal to or less than 9.

Furthermore, according to the present invention, an outside door handle for a vehicle is provided, the outside door handle including electrical insulation properties and a radio wave permeability, including a non-electric conductive handle body being mounted on an outer surface of a door of the vehicle, a first chrome film being made of chrome, the first chrome film being deposited on a surface of the handle body at a first deposition speed by sputtering, and a second chrome film being made of chrome, the second chrome film being deposited on a surface of the first chrome film at a second speed that is higher than the first deposition speed, the outside door handle in which a crack is formed within the first chrome film and within the second chrome film. In this case, it is favorable that the first deposition speed corresponds to a deposition speed which is low to an extent where the first chrome film includes an adhesive strength which is to an extent where the first chrome film is not removed from the base material, the first deposition speed corresponding to the deposition speed which is low to an extent where the first chrome film has an enhanced specularity, and the second deposition speed corresponds to a deposition speed which is high to an extent where the second chrome film has a brightness that is equal to or greater than a predetermined brightness. It is favorable that the first deposition speed corresponds to a deposition speed which is low to an extent where an internal stress generated within the first chrome film is equal to or less than a predetermined internal stress, and the second deposition speed corresponds to a deposition speed which is high to an extent where the brightness of the second chrome film is equal to a brightness of the decorative chrome plating film. In particular, it is favorable that the first deposition speed is equal to or less than 0.6 nm/sec., and the second deposition speed is equal to or greater than 1.2 nm/sec. Furthermore, it is favorable that a sum (a total film thickness) of a film thickness of the first chrome film and a film thickness of the second chrome film is equal to or greater than 30 nm. It is further favorable that the total film thickness is equal to or greater than 50 nm. It is favorable that the film thickness of the second chrome film is greater than the film thickness of the first chrome film. In this case, it is favorable that a ratio R (T2/T1) of the film thickness T2 of the second chrome film relative to the film thickness T1 of the first chrome film is equal to or greater than 5 and is equal to or less than 9.

According to the present invention, the outside door handle for the vehicle can be provided, the outside door handle including a brightness and the enhanced specularity, the brightness close to the brightness of the peripheral component being covered with the chrome plating film (the decorative chrome plating component) by the wet plating process, and including the enhanced radio wave permeability and the enhanced electric insulation properties.

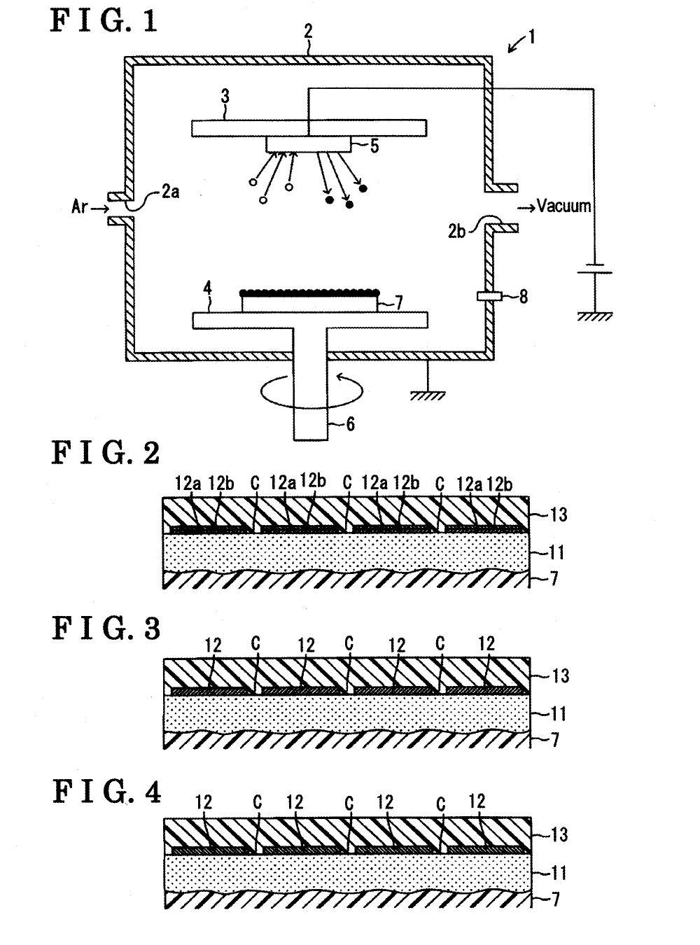

FIG. 1 is a view schematically illustrating a sputtering device that is used in a first deposition process and in a second deposition process;

FIG. 2 is a view schematically illustrating a cross section of a metallic film being manufactured by manufacturing methods according to practical examples 1 to 5;

FIG. 3 is a view schematically illustrating a cross section of a metallic film being manufactured by a manufacturing method according to a comparison example 1;

FIG. 4 is a view schematically illustrating a cross section of a metallic film being manufactured by a manufacturing method according to a comparison example 2;

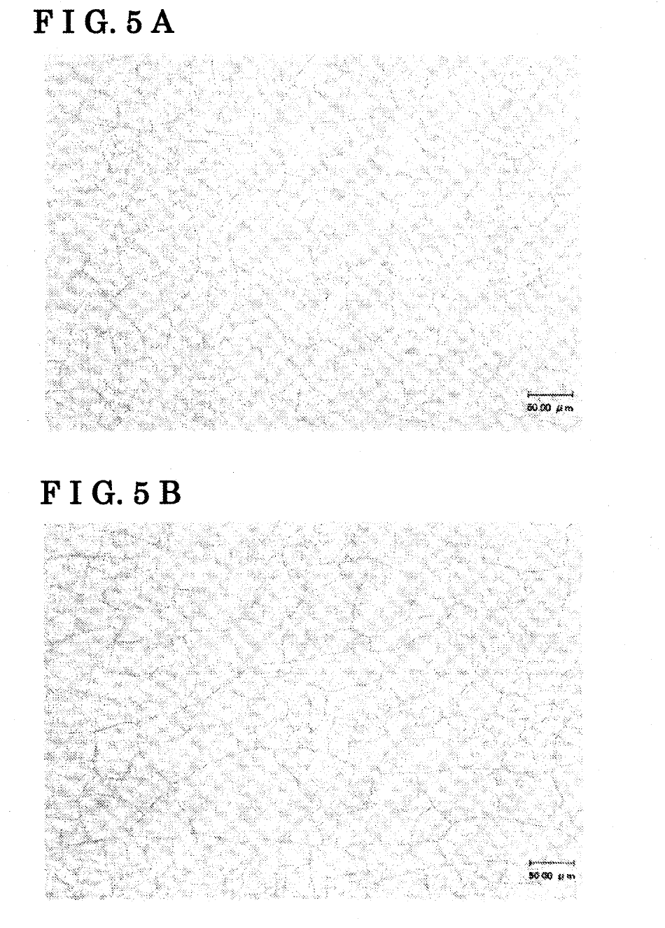

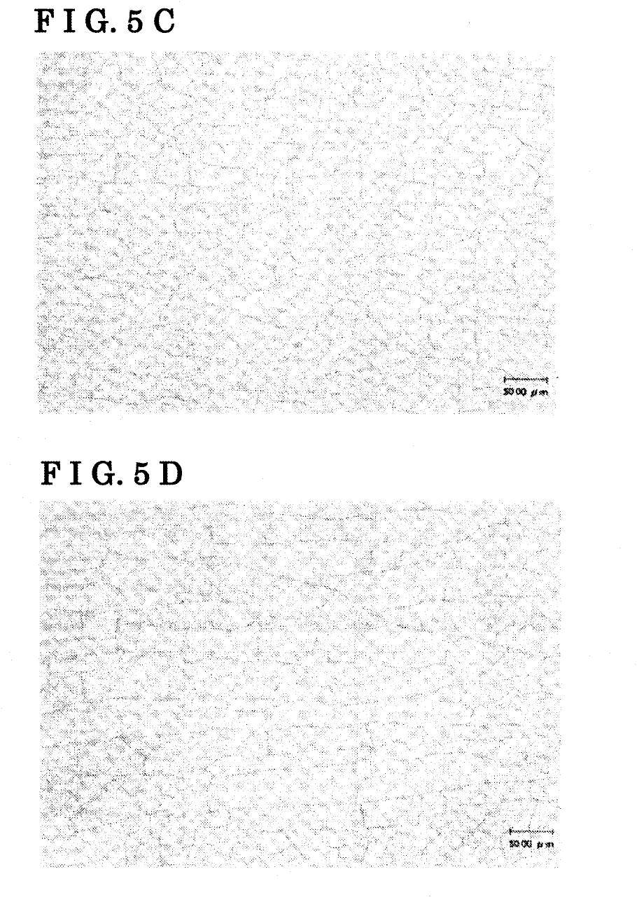

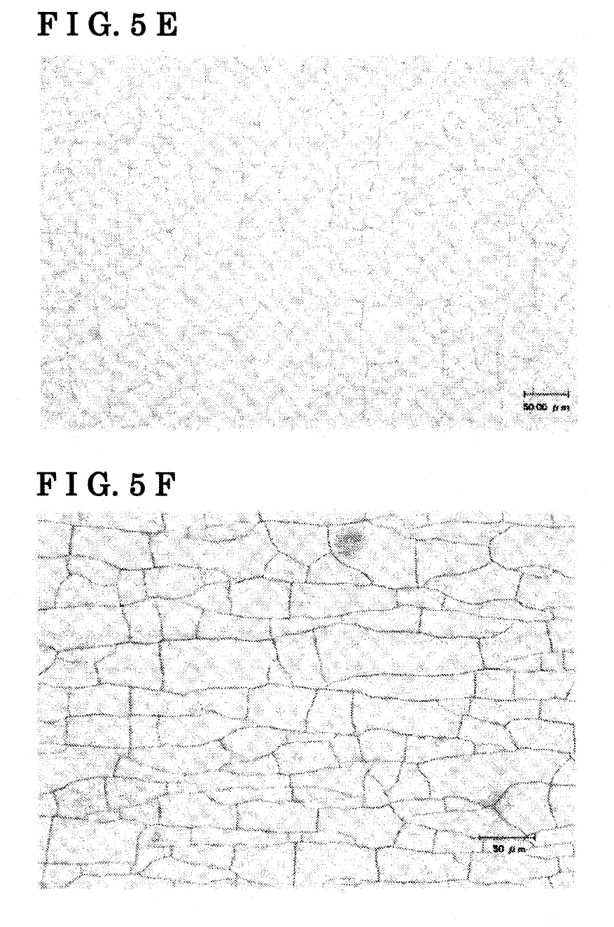

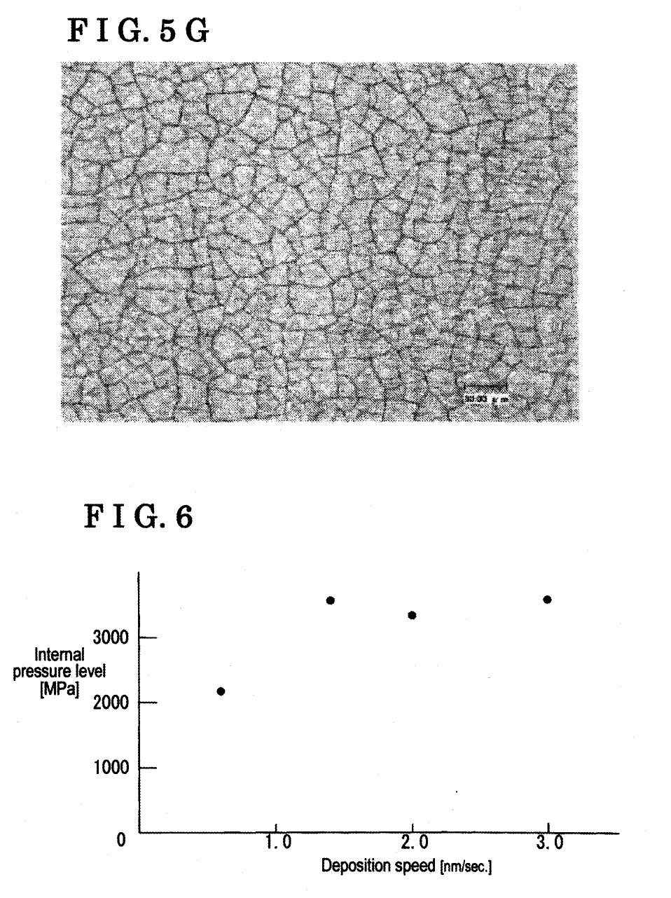

FIG. 5A is a microphotograph of a surface of the metallic film which is manufactured by the manufacturing method according to the practical example 1;

FIG. 5B is a microphotograph of a surface of the metallic film which is manufactured by the manufacturing method according to the practical example 2;

FIG. 5C is a microphotograph of a surface of the metallic film which is manufactured by the manufacturing method according to the practical example 3;

FIG. 5D is a microphotograph of a surface of the metallic film which is manufactured by the manufacturing method according to the practical example 4;

FIG. 5E is a microphotograph of a surface of the metallic film which is manufactured by the manufacturing method according to the practical example 5;

FIG. 5F is a microphotograph of a surface of the metallic film which is manufactured by the manufacturing method according to a comparison example 1;

FIG. 5G is a microphotograph of a surface of the metallic film which is manufactured by the manufacturing method according to a comparison example 2;

FIG. 6 is a graph illustrating a relationship between a deposition speed and an internal stress;

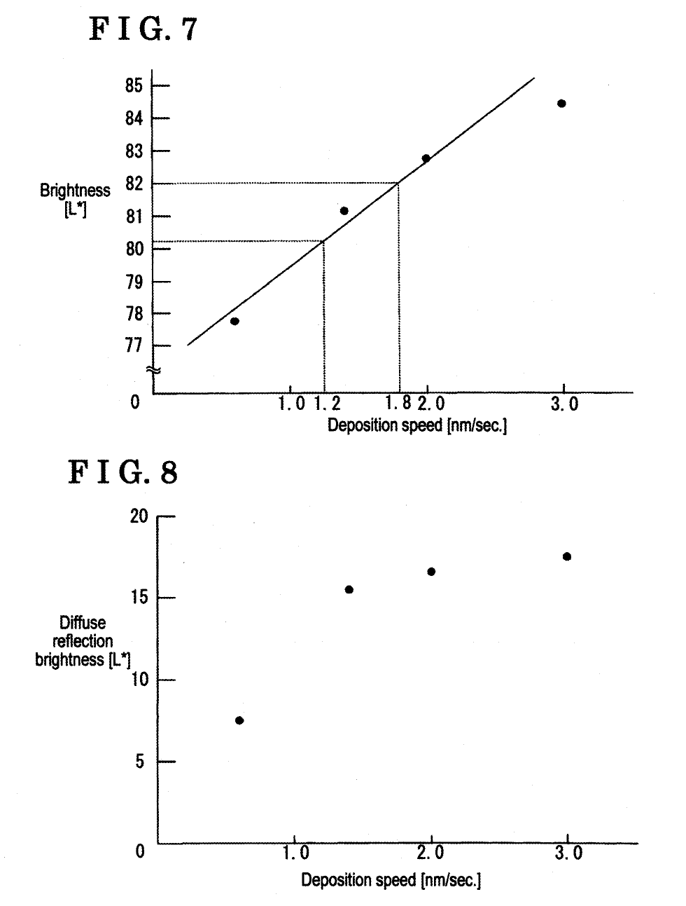

FIG. 7 is a graph illustrating a relationship between the deposition speed and a brightness;

FIG. 8 is a graph illustrating a relationship between the deposition speed and a diffuse reflection brightness;

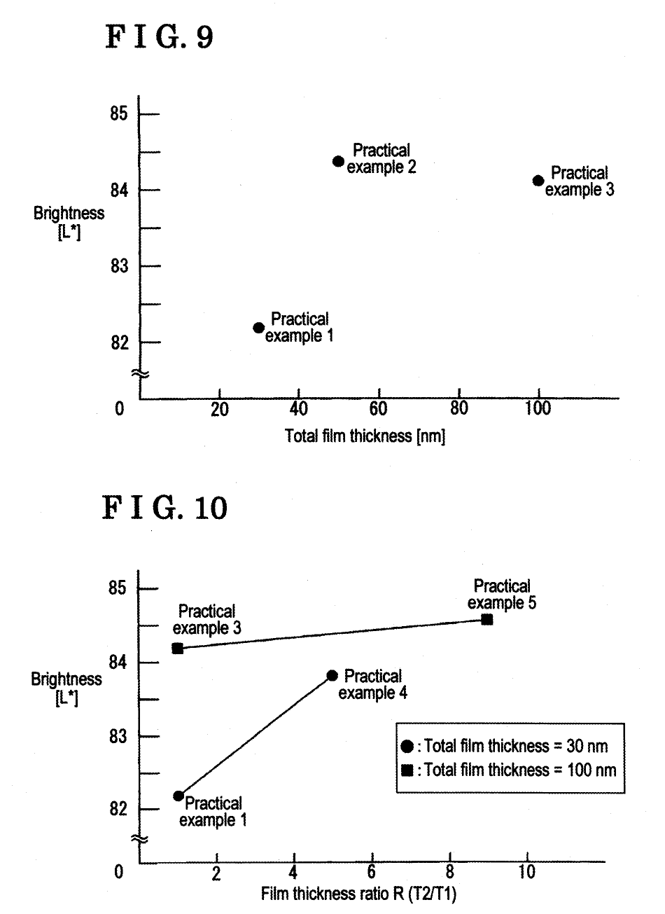

FIG. 9 is a graph illustrating a relationship between a total film thickness of a chrome film and the brightness;

FIG. 10 is a graph illustrating a relationship between a ratio R (T2/T1) of a film thickness T1 of a first chrome film and a film thickness T2 of a second chrome film and the brightness; and

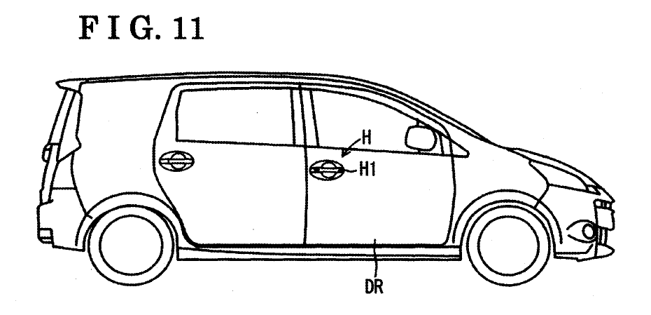

FIG. 11 is a view illustrating an outside door handle for a vehicle, the outside door handle being mounted on a vehicle door.

### MODE FOR CARRYING OUT THE INVENTION

A metallic film according to the present invention is manufactured via a first deposition process, a second deposition process and a crack forming process. FIG. 1 is a view schematically illustrating a sputtering device 1 that is used for the first deposition process and the second deposition process. As shown in FIG. 1, the sputtering device 1 according to the present embodiment includes a casing 1 that is formed with a space inside thereof, a holding plate 3, and a disc-shaped table 4. The holding plate 3 and the table 4 are positioned to face with each other in up-down directions within the casing 2 as shown in FIG. 1. The holding plate 3 is positioned above the table 4. A target 5 that is made of chrome is held at a bottom surface of the holding plate 3 shown in FIG. 1.

Moreover, the disc-shaped table 4 is connected to a rotary shaft 6 that extends in the up-down directions at a center portion of the table 4, and is rotatable about the rotary shaft 6. A base material 7 is mounted on an upper surface of the table 4 shown in FIG. 1. The base material 7 being positioned on the table 4 rotates in accordance with the rotation of the table 4. According to the present embodiment, the base material 7 corresponds to a handle body configuring a contour of an outside door handle for a vehicle. The base material 7 is made of a non-electric conductive (insulating properties) resin (an authentic resin of polycarbonate resin, or PC resin and polybutylene terephthalate resin, or PBT resin). In addition, a smooth layer being made of, for example, acryl resin, including the thickness of 20 micrometer, or 20 μm on the surface of the base material 7 by ultraviolet curing. The surface of the base material 7 is smoothened with the smooth layer.

As shown in FIG. 1, the casing 2 is provided with an inert gas inlet 2a and an exhaust opening 2b, the inert gas inlet 2a for introducing argon gas which serves as an inert gas to an inside of the casing 2, the exhaust opening 2b for exhausting air inside the casing 2. A pressure sensor 8 for detecting gas pressure level (deposition pressure level) inside the casing 2 is mounted to the casing 2.

The first deposition process and the second deposition process are operated using the sputtering device 1. In this case, first, the casing 2 is decompressed, and then, argon gas is introduced to the casing 2 so that a pressure level (deposition pressure level) within the casing 2 reaches a predetermined pressure level. Furthermore, a glow discharge is generated between the table 4 and the target 5 so that argon gas within the casing 2 is plasmatized. Accordingly, argon ion is generated. The generated argon ion (Ar⁺) hits upon the cathodic target 5 so that chrome particles are sputtered from the target 5. As shown in FIG. 1, argon ion is illustrated as white circles, and the chrome particles sputtered from the target 5 are illustrated as black circles. The chrome particles sputtered from the target 5 hit upon the surface of the base material 7 which is mounted on the table 4 being positioned to face the holding plate 3. Because the chrome particles that hit upon the surface of the base material 7 are deposited on the surface of the base material 7, a chrome film is deposited on the surface of the base material 7 (an upper surface of the smooth layer).

The aforementioned sputtering method corresponds to a glow discharge sputtering method using bipolar direct current, or bipolar DC. Alternatively, the chrome film may be deposited by using a sputtering method other than the aforementioned sputtering method, for example, a high-frequency sputtering method and a magnetron sputtering method.

In the first deposition process, the chrome film (a first chrome film) is deposited on the surface of the base material 7 at a first deposition speed by sputtering. The second deposition process is operated consecutively after the first deposition process is operated. In the second deposition process, the chrome film (a second chrome film) is further deposited on the surface of the first chrome film at a second deposition speed by sputtering. Thus, the double-layer chrome film in which the first chrome film and the second chrome film are laminated with each other is deposited on the surface of the base material 7.

The deposition speed in the second deposition process (the second deposition speed) is higher than the deposition speed in the first deposition process (the first deposition speed). That is, the chrome film is deposited at a low speed in the first deposition process, and then, the chrome film is deposited at a high speed in the second deposition process.

During the film deposition, because plasmatized, high-temperature argon ion hits upon the target 5, the chrome particles being sputtered from the target 5 have a great thermal energy. Thus, during the deposition of the chrome film, the chrome particles having the great thermal energy are accumulated on the surface of the base material. At this time, in a case where the deposition speed is high (fast), the chrome particles are prevented from being radiated sufficiently because other chrome particles being sputtered from the target 5 are adhered to the chrome particles before the chrome particles adhered to the base material 7 are sufficiently radiated. Thus, in a case where the deposition speed is high, the amount of heat stored within the chrome film is great. In a case where the amount of heat stored inside is great, the great thermal stress is generated as an internal stress within the chrome film. That is, the deposition speed of the chrome film has a correlation with the internal stress, and the greater the deposition speed is, the greater the internal stress is. Thus, in a case where the deposition speed is high, the internal stress within the chrome film is great, and the chrome film is largely deformed by the great internal stress. Accordingly, the adhesion properties of the base material and the chrome film come to be impaired (the adhesive strength is decreased). In a case where the internal stress is great, a diffuse reflection at a film surface is great, and the specularity is decreased.

Regarding to this point, according to the present embodiment, the deposition speed of the first chrome film that is deposited on the surface of the base material 7 in the first deposition process is lower than the deposition speed of the second chrome film that is deposited on a surface of the first chrome film in the following second deposition process. That is, the deposition speed of the first chrome film being directly coated on the base material 7 is low. Thus, the amount of heat stored within the first chrome film is less, and the internal stress generated due to the heat stored within the first chrome film is small. As such, because the stress within the first chrome film is relieved, the amount of deformation of the first chrome film caused by the internal stress is less, and therefore, the adhesive properties of the base material 7 and the first chrome film is sufficiently inhibited from being impaired. In addition, because the diffuse reflection is inhibited, the specularity can be enhanced.

The deposition speed of the chrome film has the correlation with the brightness of the surface of the chrome film. In particular, the lower the deposition speed is, the lower (the darker) the brightness is, and the higher the deposition speed is, the higher (the brighter) the brightness is. As described above, because the deposition speed in the first deposition process is low, the brightness of the first chrome film is low, and therefore, the surface of the first chrome film gives a dark impression. Thus, in a case where only the first chrome film is deposited on the base material 7, the adhesive properties of the chrome film and the base material are enhanced and the sufficient specularity is provided, however, the appearance of the chrome film is dark. Furthermore, the decorative chrome plating film that is deposited by a wet plating process is formed on a surface of a decorative chrome plating component that is used for automobile component. The brightness of the decorative chrome plating film is high. Accordingly, in a case where the first chrome plating film and the decorative chrome plating film are arranged next to each other, the brightness of the first chrome film and the brightness of the decorative chrome plating film do not match with each other and the uniformity is impaired.

Here, according to the present embodiment, in the second deposition process, the second chrome film is formed on the surface of the first chrome film at the second deposition speed that is high. Because the second deposition speed is greater than the first deposition speed, the brightness of the second chrome film is higher than the brightness of the first chrome film, therefore, the brightness of the second chrome film can be close to the brightness of the decorative chrome plating film. Accordingly, in a case where the peripheral component is configured by the decorative chrome plating component, the brightness of the component that includes the surface being formed with the second chrome film can be matched with the brightness of the peripheral component. Accordingly, the uniformity is prevented from being impaired. As such, according to the present embodiment, because the first deposition process at the low speed and the second deposition process at the high speed are operated, the metallic film that includes all of the enhanced adhesive properties, the sufficient specularity, and the bright appearance of the chrome film can be manufactured.

In the crack forming process that is operated after the first and second deposition processes, cracks are formed within the first chrome film and within the second chrome film. In the crack forming process, because, for example, the base material 7 on which the first chrome film and the second chrome film (hereinafter, these films may be collectively referred to as a chrome film) are formed is heated, the thermal stress is applied to the chrome film. In this case, because the base material 7 on which the chrome film is formed is inserted in a thermostatic oven and is inserted in the thermostatic oven at a predetermined temperature and for a predetermined time, thermal stress caused by a difference between a coefficient of linear expansion of the chrome film and a coefficient of linear expansion of resin of which the base material 7 is made may be applied to the chrome film. By applying thermal stress (a tensile strength) to the chrome film, the chrome film is torn to form the cracks.

The cracks are formed within the first chrome film and within the second chrome film by the crack forming process. Because the cracks are formed, the first chrome film and the second chrome film are fragmented so as to be cracked. Because the chrome film is fragmented with the cracks, the electrical insulation properties and the radio wave permeability are enhanced. Moreover, it is favorable that the chrome particles hit upon the base material 7 and the first chrome film from plural directions when the first deposition process and the second deposition process are operated in order to uniformly fragment the chrome film with the cracks. Specifically, it is favorable that the table 4 (the base material 7) rotates relative to the target 5 when the first deposition process and the second deposition process are performed. Thus, the film thickness of the chrome film is unified. Because the chrome film does not include a portion where the film thickness is partially thin, the tensile strength of the chrome film is unified. That is, in a case where the chrome film is stretched in any direction, the equivalent tensile strength may be provided. Thus, when the stress is applied to the chrome film by the crack forming process, the cracks are uniformly formed. As a result, the electrical insulation properties can be prevented from being low along a specific direction, and the enhanced electrical insulation properties and the enhanced radio wave permeability can be provided.

Meanwhile, a protection film coating process may be operated after the crack forming process. A transparent resin, for example, an acrylic urethane coating material, is coated on the base material 7 on which the first chrome film and the second chrome film are formed by the protection film coating process. Because the surface of the second chrome film is covered with the protection film, the cracks being formed in the crack forming process can be prevented from being deformed. Moreover, because the protection film is formed, the environmental performance, for example, scratch resistance, abrasion resistance, and weather resistance, is enhanced.

### Practical Examples

The smooth layer being made of the acryl resin and having the thickness of 20 μm was formed on the surface of the base material 7 that is used for the handle body of the outside door handle of the vehicle. Then, the base material 7 was mounted on the table 4 of the sputtering device 1 shown in FIG. 1. Moreover, a bulk metal (a solid metal) of chrome as the target 5 was mounted on the holding plate 3. Then, the chrome film (the first chrome film) was deposited on the surface of the base material 7 (the surface of the smooth layer) (the first deposition process) by the operation of the sputtering device 1.

The chrome film (the second chrome film) was deposited on the surface of the first chrome film within the sputtering device 1 (the second deposition process) consecutively after the first deposition process. As such, the double-layer chrome film that is configured by the first chrome film and the second chrome film was deposited by sputtering.

Here, a deposition condition (a deposition speed, a film thickness, a deposition pressure level) when the first deposition process is operated and a deposition condition (the deposition speed, the film thickness, the deposition pressure level) when the second deposition process is operated were set as shown in practical examples 1 to 5 in Table 1. Then, the first chrome film and the second chrome film were deposited on the surface of the base material in accordance with each of the deposition conditions that were set. As is clear from Table 1, according to each of the practical examples, the deposition speed when the second deposition process is operated is higher than the deposition speed when the first deposition process is operated.

TABLE 1

| | | Deposition | Film | Deposition |
|---|---|---|---|---|
| | | speed | thick- | pressure |
| | | [nanometer/ | ness | level |
| | Process | sec.] | [nm] | [Pascal] |
| Practical | First deposition process | 0.6 | 15 | 0.3 |
| example 1 | Second deposition process | 3 | 15 | 0.3 |
| Practical | First deposition process | 0.6 | 25 | 0.3 |
| example 2 | Second deposition process | 3 | 25 | 0.3 |
| Practical | First deposition process | 0.6 | 50 | 0.3 |
| example 3 | Second deposition process | 3 | 50 | 0.3 |
| Practical | First deposition process | 0.6 | 5 | 0.3 |
| example 4 | Second deposition process | 3 | 25 | 0.3 |
| Practical | First deposition process | 0.6 | 10 | 0.3 |
| example 5 | Second deposition process | 3 | 90 | 0.3 |

When the first deposition process and the second deposition process are operated, the base material 7 was rotated relative to the target 5 to have the chrome particles sputtered from the target 5 hit upon the respective surfaces of the base material 7 and of the first chrome film from plural directions. In this case, the rotation speed of the table 4 on which the base material 7 is mounted was 120 rotations per minute, or 120 rpm. After the deposition process, the base material 7 was inserted in the thermostatic oven at the atmospheric temperature of 80° C. for 30 minutes to be heated. Then, thermal stress caused by a difference between a coefficient of linear expansion of the base material 7 and coefficients of linear thermal expansion of the first chrome film and of the second chrome film was applied to the first chrome film and the second chrome film. Accordingly, the cracks were formed within the first chrome film and within the second chrome film (the crack forming process). Then, the acrylic urethane coating material as the protection film was coated on the surface of the second chrome film being formed with the cracks so as to include the thickness of 20 μm and was thermally dried. As such, the metallic film was manufactured via the first deposition process, the second deposition process, and the crack forming process. Hereinafter, the metallic film on which the chrome film is deposited in accordance with each of the deposition conditions shown in the practical examples is referred to as the metallic film that is manufactured by each of the manufacturing methods according to the practical examples.

FIG. 2 is a view schematically illustrating a cross section of the metallic film that is manufactured by the manufacturing methods according to the practical examples. As shown in FIG. 2, a smooth layer 11, a first chrome film 12a, a second chrome film 12b, and a protection film 13 are laminated in the aforementioned order on the surface of the base material 7. Cracks C are formed by the crack forming process. Because the cracks C are formed, the first chrome film 12a is fragmented and the second chrome film 12b is fragmented.

As shown in FIG. 11, the base material 7 on which the metallic film being manufactured by the manufacturing methods according to the practical examples is formed is mounted on an outer surface of a door DR of a vehicle serving as a handle body H1 of an outside door handle H for the vehicle. Thus, the outside door handle H for the vehicle is provided with the non-electric conductive handle body H1 (the base material 7), the first chrome film, and the second chrome film. The handle body H1 is mounted on the outer surface of the door DR of the vehicle and is operated by the user. The first chrome film is made of chrome being deposited on the surface of the handle body H1 at the first deposition speed by sputtering. The second chrome film is made of chrome being deposited on the surface of the first chrome film at the second deposition speed that is higher than the first deposition speed by sputtering. The cracks are formed within the first chrome film and within the second chrome film.

### Comparison Example

The base material 7 on which the smooth layer being made of acryl resin and having the thickness of 20 μm was formed is mounted on the table 4 of the sputtering device 1 shown in FIG. 1. Moreover, the bulk metal (the solid metal) of chrome as the target 5 is mounted on the holding plate 3. Then, a single-layer chrome film was deposited on the surface of the base material 7 (the deposition process) by the operation of the sputtering device 1 under a setting of a deposition condition as below.

Deposition speed: 0.6 nanometer per second (nm/sec.)

Film thickness: 30 nm

Deposition pressure level: 0.3 Pascal

The base material 7 was rotated relative to the target 5 during the deposition process. In this case, the rotation speed of the table 4 on which the base material 7 is mounted was 120 rpm. After the deposition process, the base material 7 was inserted in the thermostatic oven at the atmospheric temperature of 80° C. for 30 minutes to be heated. Then, thermal stress caused by a difference between the coefficient of linear expansion of the base material 7 and the coefficient of linear expansion of the chrome film was applied to the chrome film. Accordingly, the cracks were formed within the chrome film (the crack forming process). Then, the acrylic urethane coating material was coated as the protection film on the surface of the chrome film being formed with the cracks so as to include the thickness of 20 μm and was thermally dried. As such, the metallic film was manufactured.

FIG. 3 is a view schematically illustrating a cross section of the metallic film being manufactured by the manufacturing method according to the comparison example 1. As shown in FIG. 3, the smooth layer 11, a chrome film 12, and the protection film 13 are laminated in the aforementioned order on the surface of the base material 7. The deposition speed (0.6 nm/sec.) of the chrome film 12 according to the comparison example 1 corresponds to be equal to the deposition speed of the first chrome film 12a according to the practical examples in Table 1. The cracks C are formed by the crack forming process. Because the cracks C are formed, the chrome film 12 is fragmented.

### Comparison Example 2

The base material 7 on which the smooth layer being made of acryl resin and having the thickness of 20 μm was formed is mounted on the table 4 of the sputtering device 1 shown in FIG. 1. Moreover, the bulk metal (the solid metal) of chrome as the target 5 is mounted on the holding plate 3. Then, the single-layer chrome film was deposited on the surface of the base material 7 (the deposition process) by the operation of the sputtering device 1 under the setting of a deposition condition as below.

Deposition speed: 3.0 nm/sec.

Film thickness: 30 nm

Deposition pressure level: 0.3 Pal

Furthermore, the base material 7 was rotated relative to the target 5 during the deposition process. In this case, the rotation speed of the table 4 on which the base material 7 is mounted was 120 rpm. After the deposition process, the base material 7 was inserted in the thermostatic oven at the atmospheric temperature of 80° C. for 30 minutes to be heated. Then, thermal stress caused by the difference between the coefficient of linear expansion of the base material 7 and the coefficient of linear expansion of the chrome film was applied to the chrome film. Accordingly, the cracks were formed within the chrome film (the crack forming process). Then, the acrylic urethane coating material was coated as the protection film on the surface of the chrome film being formed with the cracks so as to include the thickness of 20 μm and was thermally dried. As such, the metallic film was manufactured.

FIG. 4 is a view schematically illustrating a cross section of the metallic film being manufactured by the manufacturing method according to the comparison example 2. As shown in FIG. 4, the smooth layer 11, the chrome film 12, and the protection film 13 are laminated in the aforementioned order on the surface of the base material 7. The deposition speed (3.0 nm/sec.) of the chrome film 12 according to the comparison example 2 corresponds to be equal to the deposition speed of the second chrome film 12b according to the practical examples in Table 1. The cracks C are formed by the crack forming process. Because the cracks C are formed, the chrome film 12 is fragmented.

FIG. 5A is a microphotograph of the metallic film which is manufactured by the manufacturing method according to the practical example 1. FIG. 5B is a microphotograph of the metallic film which is manufactured by the manufacturing method according to the practical example 2. FIG. 5C is a microphotograph of the metallic film which is manufactured by the manufacturing method according to the practical example 3. FIG. 5D is a microphotograph of the metallic film which is manufactured by the manufacturing method according to the practical example 4. FIG. 5E is a microphotograph of the metallic film which is manufactured by the manufacturing method according to the practical example 5. FIG. 5F is a microphotograph of the metallic film which is manufactured by the manufacturing method according to the comparison example 1. FIG. 5G is a microphotograph of the metallic film which is manufactured by the manufacturing method according to the comparison example 2. As is clear from these figures, the net-shaped cracks are formed on each of the metallic films of all the examples.

The brightness, the diffuse reflection brightness, and the surface resistance of the metallic film being manufactured by the manufacturing methods according to the examples were measured. In this case, the brightness, the diffuse reflection brightness, and the surface resistance were measured before the protection film is coated. The spectrocolorimeter CM-700d of Konica Minolta, Inc. was used for the measurement of the brightness and the diffuse reflection brightness. In a case where the brightness is measured, the measurement mode is set to be specular component included measurement, or SCI measurement (total reflection measurement). In a case where the diffuse reflection brightness is measured, the measurement mode is set to be specular component excluded measurement, or SCE measurement (specular reflection light removal). It is determined that the higher the brightness measured by the SCI measurement is, the brighter the appearance is given. It is determined that the higher the diffuse reflection brightness measured by SCE measurement is, the stronger the diffuse reflection light is, that is, the specularity is low. Furthermore, the brightness is standardized by international commission on illumination, or CIE and was expressed by L* of L*a*b* color system that is adopted in Japanese Industrial Standard, or JIS (JISZ8729) in Japan. Moreover, a sheet resistance measuring device is used for measuring the surface resistance. In this case, the resistance value that is equal to or greater than 10⁸ ohms per square, or 10⁸ Ω/sq. is measured by Hiresta UPMCP-HT450 of Mitsubishi Chemical Analytech Co., Ltd. The resistance value that is lower than 10⁸ Ω/sq. is measured by Loresta GPMCP-T600 of Mitsubishi Chemical Analytech Co., Ltd.

Furthermore, an appearance evaluation, an adhesive properties evaluation, an antenna feature evaluation, and a touch sensor feature evaluation of the metallic films being manufactured by the manufacturing methods according to the examples were performed. Upon evaluating the appearance, each of the surfaces of the metallic films being manufactured by the manufacturing methods according to the examples was visually observed. In a case where the brightness and the specularity of the surface is determined to be similar to the brightness and the specularity of the decorative chrome plating film that is deposited by the wet plating process and to be able to sufficiently generate the uniformity with the decorative chrome plating component, it was evaluated as passed (✓), and if not, it was evaluated as failed (X). Furthermore, upon evaluating the adhesive properties, a base material (sample) on which the metallic film that is manufactured by each of the manufacturing methods of the examples is formed was stored in a xenon lamp accelerated weather meter and the accelerated weathering test (a defined amount of an ultraviolet light is radiated to the base material, and after that, the base material is soaked in hot water) was performed. The adhesive properties of the sample after the accelerated weather meter were evaluated. In this case, the metallic film being formed at each of the samples was divided into squares in 10 rows and 10 columns by, for example, a cutter. An adhesive tape was stuck onto the divided square area, and then, was pulled to be removed in a direction where the tape and the surface of the base material configure a predetermined angle. Then, a removal state of the metallic film of the area where the adhesive tape is applied, the metallic film that is configured with the squares, was observed. In a case where there was no squares removed, it was evaluated as passed (✓), and in a case where the square removed was equal to or greater than one, it was evaluated as failed (X).

Meanwhile, the antenna feature evaluation corresponds to an evaluation based on whether an antenna precisely receive signals from a smart key that is provided outside, the antenna that is provided inside the door handle for the smart entry system including the handle body that includes the surface being formed with the metallic film being manufactured by the manufacturing methods according to the examples. In a case where the antenna precisely receives the signals from the door handle for the smart entry system, it was evaluated as passed (✓). In a case where the antenna does not precisely receive the signals from the door handle for the smart entry system, it was evaluated as failed (X). In a case where the antenna feature evaluation is passed (✓), the metallic film includes the enhanced radio wave permeability. The touch sensor feature evaluation corresponds to an evaluation whether a misoperation relating to an opening and closing of a vehicle door is performed when a human hand touches a position other than a predetermined position of the door handle for the smart entry system including the handle body that includes the surface being formed with the metallic film being manufactured by the manufacturing methods according to the examples. In a case where the misoperation is not performed, it was evaluated as passed (✓). In a case where the misoperation is performed, it was evaluated as failed (X). In a case where the touch sensor feature evaluation is passed) (✓), the metallic film has enhanced electrical insulation properties.

In Table 2, the respective measurement values of the brightness and of the diffuse reflection brightness, the appearance evaluation result, the adhesive properties evaluation result, the measurement value of the surface resistance, and the antenna feature evaluation result and the touch sensor feature evaluation result of the metallic film being manufactured by the manufacturing methods according to the examples, the antenna feature evaluation result and the touch sensor feature evaluation result in a case where the handle body including the surface being formed with the metallic film being manufactured by the manufacturing methods according to the examples are shown is used. In Table 2, the deposition conditions (deposition speed, film thickness, deposition pressure level) of the metallic film being manufactured by the manufacturing methods according to the examples are also shown. Meanwhile, regarding the deposition speed in Table 2, the deposition speed in the first deposition process is shown in each of upper sections of the practical examples 1 to 5. The deposition speed in the second deposition process is shown in each of lower sections of the practical examples 1 to 5. Furthermore, regarding the film thickness in Table 2, the film thickness of the first chrome film is shown in each of upper portions of the left half of the practical examples 1 to 5. The film thickness of the second chrome film is shown in each of lower portions of the left half of the practical examples 1 to 5. The total film thickness (a sum of the film thickness of the first chrome film and the second chrome film) is shown in each of the right half of the practical examples 1 to 5.

TABLE 2

| | Practical | | Practical | | Practical | | Practical | | Practical | | Comparison | Comparison |
|---|---|---|---|---|---|---|---|---|---|---|---|---|
| | example 1 | | example 2 | | example 3 | | example 4 | | example 5 | | example 1 | example 2 |
| Deposition | 0.6 | | 0.6 | | 0.6 | | 0.6 | | 0.6 | | 0.6 | 3 |
| speed | 3 | | 3 | | 3 | | 3 | | 3 | | | |
| [nm/sec.] | | | | | | | | | | | | |
| Film thickness | 15 | 30 | 25 | 50 | 50 | 100 | 5 | 30 | 10 | 100 | 30 | 30 |
| [nm] | 15 | | 25 | | 50 | | 25 | | 90 | | | |

| | | | | | | | |
|---|---|---|---|---|---|---|---|
| Deposition | 0.3 | 0.3 | 0.3 | 0.3 | 0.3 | 0.3 | 0.3 |
| pressure | | | | | | | |
| level[Pa] | | | | | | | |
| Brightness | 82.08 | 84.33 | 84.16 | 83.79 | 84.58 | 77.36 | 84.42 |
| [L*] | | | | | | | |
| Diffuse | 9.73 | 9.24 | 10.38 | 9.84 | 11.13 | 7.46 | 17.54 |
| reflection | | | | | | | |
| brightness | | | | | | | |
| [L*] | | | | | | | |
| Appearance | ✓ | ✓ | ✓ | ✓ | ✓ | x | x |
| evaluation | | | | | | | |
| Adhesive | ✓ | ✓ | ✓ | ✓ | ✓ | ✓ | x |
| properties | | | | | | | |
| evaluation | | | | | | | |
| Surface | 3.6 × 10⁸ | 6.5 × 10⁸ | 8.1 × 10⁸ | 1.3 × 10⁸ | 6.4 × 10⁸ | 2.2 × 10⁸ | 5.2 × 10⁸ |
| resistance | | | | | | | |
| [Ω/sq.] | | | | | | | |
| Antenna | ✓ | ✓ | ✓ | ✓ | ✓ | ✓ | ✓ |
| feature | | | | | | | |
| evaluation | | | | | | | |
| Touch sensor | ✓ | ✓ | ✓ | ✓ | ✓ | ✓ | ✓ |
| feature | | | | | | | |
| evaluation | | | | | | | |

As shown in Table 2, the antenna feature evaluation and the touch sensor evaluation are shown as passed (✓) in all the examples. Furthermore, the metallic film being manufactured by the manufacturing methods according to the practical examples 1 to 5 gives the enhanced specularity and the bright metal appearance. The appearance evaluation of each of the metallic films is passed (✓). On the other hand, the metallic film being manufactured by the manufacturing method according to the comparison example 1 gives the enhanced specularity but the dark metal appearance. The appearance evaluation is failed (X) in terms of the brightness. Moreover, the metallic film being manufactured by the manufacturing method according to the comparison example 2 gives the bright metal appearance, however, the low specularity and foggy appearance. The appearance evaluation is failed (X) in terms of the specularity (the diffuse reflection brightness). Moreover, the adhesive properties evaluation is passed (✓) with the practical embodiments 1 to 5 and the comparison example 2, however, is failed (X) with the comparison example 2. From this, it is clear that each of the metallic films being manufactured by the manufacturing methods of the practical examples includes the favorable adhesive properties, the good appearance designability in terms of the brightness and the specularity, and the enhanced electrical insulation properties and the enhanced radio wave permeability so that the metallic films are highly effective.

(The Relationship Between the Deposition Speed and the Internal Stress)

To investigate the relationship between the deposition speed and the internal stress of the chrome film, the chrome film was deposited on a glass base material at plural deposition speeds (0.6 nm/sec., 1.4 nm/sec., 2.0 nm/sec. and 3.0 nm/sec.) by sputtering by the use of the puttering device 1 shown in FIG. 1. The film thickness is 30 nm and the deposition pressure level is 0.3 Pa. The glass base material was rotated relative to the target 5 during the deposition process. After the deposition process, the glass base material was inserted in the thermostatic oven at the atmospheric temperature of 80° C. for 30 minutes to be heated. Accordingly, the cracks were formed within the chrome film. Then, the internal stress within the chrome film was measured. A document “Journal of the Society of Materials Science, Japan” (J. Soc. Mat. Sci., Japan, Vol 51, No. 12, pp. 1429-1435, December 2002) was referred for the measurement of the internal stress. The internal stress was measured by a constant penetration method.

Table 3 illustrates the measured internal stress per deposition speed. FIG. 6 is a graph illustrating the relationship between the deposition speed and the internal stress given from Table 3. A lateral axis corresponds to the deposition speed (nm/sec.) and a longitudinal axis corresponds to the internal stress (MPa).

TABLE 3

| Deposition speed [nm/sec] | Internal stress [MPa] |
|---|---|
| 0.6 | 2168.6 |
| 1.4 | 3567.3 |
| 2.0 | 3335.2 |
| 3.0 | 3590.8 |

As is clear from FIG. 6, the internal stress decreases as the deposition speed decreases. Moreover, in a case where the deposition speed corresponds to be equal to or greater than 1.4 nm/sec., the internal stress is equal to or greater than 3000 MPa. On the other hand, in a case where the deposition speed corresponds to 0.6 nm/sec., the internal stress is equal to or less than 3000 MPa (in particular, approximately 2000 MPa). In a case where the internal stress is equal to or less than 3000 MPa, the effect of the internal stress affecting the decrease of the adhesive strength is considered to be less. From this, because the first chrome film is deposited on the surface of the base material 17 at the low deposition speed that is equal to or less than 0.6 nm/sec., it is clear that the stress can be relieved by decreasing the internal stress sufficiently. In a case where the internal stress is small, the impairment of the adhesive properties of the base material 7 and the first chrome film can be sufficiently inhibited. Furthermore, the specularity after the crack forming process can be enhanced. Accordingly, it is favorable that the deposition speed during the first deposition process is equal to or less than 0.6 nm/sec.

(The Relationship Between the Deposition Speed, the Brightness, and the Diffuse Reflection Brightness)

To investigate the relationship between the deposition speed, the brightness, and the diffuse reflection brightness of the chrome film, the chrome film was deposited on a glass base material at plural deposition speeds (0.6 nm/sec., 1.4 nm/sec., 2.0 nm/sec. and 3.0 nm/sec.) by sputtering by the use of the sputtering device 1 shown in FIG. 1. The film thickness is 30 nm and the deposition pressure level is 0.3 Pa. The glass base material was rotated relative to the target 5 during the deposition process. After the deposition process, the glass base material was inserted in the thermostatic oven at the atmospheric temperature of 80° C. for 30 minutes to be heated. Accordingly, the cracks were formed within the chrome film. Then, the brightness and the diffuse reflection brightness (L* of the L*a*b* color system) were measured by the same methods as the methods of the aforementioned examples.

Table. 4 illustrates the measured brightness and diffuse reflection brightness per deposition speed. FIG. 7 is a graph illustrating the relationship between the deposition speed and the brightness given from FIG. 4. FIG. 8 is a graph illustrating the relationship between the deposition speed and the diffuse reflection brightness given from FIG. 4. A lateral axis corresponds to the deposition speed (nm/sec.) and a longitudinal axis corresponds to the brightness (−).

TABLE 4

| Deposition speed | | Diffuse reflection |
|---|---|---|
| [nm/sec] | Brightness [L*] | brightness [L*] |
| 0.6 | 77.36 | 7.46 |
| 1.4 | 81.33 | 15.57 |
| 2.0 | 82.71 | 16.6 |
| 3.0 | 84.42 | 17.54 |

As is clear from FIG. 7, the brightness L* increases as the deposition speed increases. This is because the oxidization degree of the film is considered to come to be low as the deposition speed increases. Because the brightness L* of the decorative chrome plating film deposited by the wet plating process corresponds to be approximately 82-83, the brightness L* is equal to or greater than 80 and the brightness of the surface can be close to the brightness of the decorative chrome plating component in a case where the deposition speed is equal to or greater than 1.2 nm/sec. Thus, it is favorable that the deposition during the second deposition process is equal to or greater than 1.2 nm/sec. In addition, in a case where the deposition speed corresponds to 1.8 nm/min., the brightness L* is equal to or greater than 82, and the brightness of the surface can be further close to the brightness of the decorative chrome plating component. Accordingly, it is further favorable that the deposition speed during the second deposition process is equal to or greater than 1.8 nm.

As is clear from FIG. 8, the diffuse reflection brightness L* increases as the deposition speed increases. The high diffuse reflection brightness L* means that an irregular reflection often occurs and a direct reflection strength is low (the specularity is low). That is, the higher the diffuse reflection brightness L* is, the lower the specularity is. The lower the diffuse reflection brightness L* is, the greater the specularity is enhanced. From these, it is clear than the specularity increases as the deposition speed decreases. In the practical examples 1 to 5, because the deposition speed of the first chrome film is low as 0.6 nm/sec., the specularity can be enhanced. Furthermore, because the diffuse reflection brightness of the decorative chrome plating film corresponds to approximately 10, the diffuse reflection brightness can be sufficiently decreased, and as a result, the enhanced specularity (that is, the sufficient specularity) that corresponds to be equal to the specularity of the decorative chrome plating can be provided in a case where the deposition speed is equal to or lower than 0.6 nm/sec. Meanwhile, in the aforementioned practical examples 1 to 5, the deposition speed of the first chrome film (the chrome film that is disposed at an inner side) corresponds to the low speed and the deposition speed of the second chrome film (the chrome film that is disposed at an outer side) corresponds to the high speed. Thus, even in a case where only the deposition speed of the chrome film that is disposed at the inner side is set at the low speed (0.6 nm/sec.), it is clear that the diffuse reflection brightness of the manufactured metallic film decreases and the specularity increases.

FIG. 9 is a graph illustrating the relationship between the total film thickness (the sum of the film thickness of the first chrome film and the film thickness of the second chrome film) and the brightness of the chrome film being deposited by the deposition conditions shown in the practical examples 1, 2 and 3. According to the deposition conditions shown in the practical examples 1, 2 and 3, a film thickness T1 of the first chrome film and a film thickness T2 of the second film thickness are equal to each other. That is, FIG. 9 illustrates the relationship between the total film thickness and the brightness under a condition where a ratio R (T2/T1) of the film thickness T2 of the second chrome film relative to the film thickness T1 of the first chrome film is constant.

As shown in FIG. 9, the greater the total film thickness is, the higher the brightness tends to be. Moreover, in a case where the total film thickness is equal to or greater than 30 nm, the brightness is equal to or greater than 82 [L*]. From this, it is favorable that the total film thickness is equal to greater than 30 nm. It is further favorable that the total film thickness is equal to or greater than 50 nm. In a case where the total film thickness is equal to or greater than 50 nm, the brightness can be further enhanced. In a case where the total film thickness is equal to or greater than 50 nm, it is highly possible that the film thickness of a portion where the film thickness is partially thin due to the variation of the film thickness is equal to or greater than 30 nm even in a case where the chrome film is formed with the portion. Thus, the brightness of the whole film-coated area can be maintained equal to or greater than a predetermined brightness.

FIG. 10 is a graph illustrating a relationship between the ratio R (T2/T1) and the brightness, the ratio R of the thickness T1 of the first chrome film and the film thickness T2 of the second chrome film being deposited by the deposition conditions shown in the practical examples of the 1, 3, 4 and 5. Here, the total film thickness of the chrome film deposited by each of the deposition conditions shown in the practical examples 1 and 4 corresponds to 30 nm. The total film thickness of the chrome film deposited by each of the deposition conditions shown in the practical examples 3 and 5 corresponds to 100 nm. Thus, the relationship between the ratio R and the brightness in a case where the total film thickness corresponds to 30 nm according to the practical examples 1 and 4 is shown. The relationship between the ratio R and the brightness in a case where the total film thickness corresponds to 100 nm according to the practical examples 3 and 5 is shown.

As shown in FIG. 10, the greater the ratio R is, the higher the brightness tends to be. Thus, it is favorable that the total film thickness ratio R is greater than 1 in order to obtain the metallic luster that includes higher brightness. That is, it is favorable that the first chrome film and the second chrome film are deposited so that the second chrome film is thicker than the first chrome film. Meanwhile, the deposition speed of the second chrome film is faster than the deposition speed of the first chrome film. Under the condition where the total film thickness is in common, the deposition time required in a case where the second chrome film is thicker than the first chrome film is shorter than the deposition time required in a case where the first chrome film and the second chrome film include the same thickness, and in a case where the second chrome film is thinner than the first chrome film. Thus, in a case where the first chrome film and the second chrome film are deposited so that the second chrome film deposited in the second deposition process is thicker than the first chrome film deposited in the first deposition process, the deposition time can be shortened. Accordingly, the productivity can be enhanced.

It is favorable that the ratio R is equal to or greater than 5. In a case where the ratio R is equal to or greater than 5, the deposition time can be greatly shortened. Meanwhile, it is favorable that the ratio R is equal to or less than 9. In view of the reduction of material cost, it is favorable that the film thickness of the chrome film is thin. If the ratio R is too large in a case where the total film thickness is thin, the first chrome film is too thick, leading to a concern of the decrease of the adhesive properties. Thus, it is favorable that the ratio R is equal to or less than 9. That is, the favorable region of the ratio R is equal to or greater than 5 and is equal to or less than 9.

As mentioned above, the manufacturing method of the metallic film according to the present invention includes a first deposition process depositing a first chrome film being made of chrome on the surface of the base material at a first deposition speed by sputtering, a second deposition process depositing a second chrome film being made of chrome on a surface of the first chrome film at a second deposition speed that is higher than the first deposition speed by sputtering, and a crack forming process forming a crack within the first chrome film and within the second chrome film by an application of a stress to the first chrome film and to the second chrome film.

According to the present embodiment, because the metal being used during the deposition process is chrome only, costs for a film material and for an equipment can be reduced comparing to a case where two or more types of metals are used. In addition, because the first chrome film is deposited on the surface of the base material at the low speed in the first deposition process (the first deposition process), the amount of heat stored within the first chrome film is reduced. Because the stored amount of heat is reduced, the internal stress generated within the first chrome film is decreased (the stress is relieved). As a result, the adhesive properties of the base material and the chrome film can be inhibited from being impaired and the enhanced specularity can be provided. In addition, in the second deposition process, because the second chrome film is deposited on the surface of the first chrome film deposited on the surface of the base material in the first deposition process at the speed (the second deposition speed) higher than the first deposition speed, the brightness of the chrome film (the second chrome film) corresponds to be substantially equal to the brightness of the decorative chrome plating film. Thus, the uniformity between the component formed with the metallic film manufactured by the manufacturing method of the present embodiment and the peripheral component being covered with another decorative chrome plating film can be generated. That is, according to the present embodiment, the metallic film that includes the enhanced adhesive properties of the chrome film, the bright appearance that corresponds to the appearance of the decorative chrome plating, and the sufficient specularity can be manufactured.

In addition, because the cracks are formed within the first chrome film and within the second chrome film in the crack forming process, the electrical insulation properties and the radio wave permeability can be enhanced. As such, according to the present embodiment, the manufacturing method of the metallic film that includes the favorable adhesive properties with the base material 7, that includes the brightness close to the brightness of the decorative chrome film and the sufficient specularity, and that has the enhanced radio wave permeability and the enhanced electrical insulation properties can be provided.

Moreover, the first deposition speed corresponds to a deposition speed which is low to an extent where the first chrome film includes an adhesive strength which is to an extent where the first chrome film is not removed from the base material (an extent where the first chrome film is evaluated as passed in the aforementioned adhesive properties evaluation), the first deposition speed corresponding to the deposition speed which is low to an extent where the first chrome film has an enhanced specularity, and the second deposition speed corresponds to a deposition speed which is high to an extent where the second chrome film has a brightness that is equal to or greater than a predetermined brightness (for example, 80 in a case where the brightness is expressed by L*). Moreover, the first deposition speed corresponds to a deposition speed which is low to an extent where an internal stress generated within the first chrome film is equal to or less than a predetermined internal stress (for example, 3000 MPa), and the second deposition speed corresponds to a deposition speed which is high to an extent where the brightness of the second chrome film is equal to a brightness (for example, equal to or greater than 80 in a case where the brightness is expressed by L*) of a decorative chrome plating film. In particular, the first deposition speed is equal to or less than 0.6 nm/sec., and the second deposition speed is equal to or greater than 1.2 nm/sec.

Accordingly, the adhesive properties of the base material 7 and the first chrome film can be sufficiently inhibited from being impaired. A malfunction in which, for example, the chrome film is removed can be prevented. The sufficient specularity can be provided. The brightness of the second chrome film can be sufficiently close to the brightness of the decorative chrome plating component.

Because the sum (the total film thickness) of the first chrome film and the second chrome film is set equal to or greater than 30 nm, the brightness of the metallic film according to the present embodiment can be further close to the brightness of the decorative chrome plating film. Because the chrome film is deposited so that the film thickness T2 of the second chrome film is thicker than the film thickness T1 of the first chrome film, that is, so that the ratio R (T2/T1) is greater than 1, the deposition time can be shortened.

Because the metallic film according to the aforementioned embodiment is formed on the surface of the handle body of the outside door handle for the vehicle, the outside door handle for the vehicle can be provided, the outside handle that includes favorable adhesive properties and that includes the enhanced radio wave permeability and the enhanced electrical insulation properties without impairing the uniformity of the metallic film with the peripheral component being provided with the decorative chrome plating film deposited by the wet plating process.

1. A manufacturing method of a metallic film being formed on a surface of a nonelectric conductive base material, the manufacturing method comprising:
a first deposition process depositing a first chrome film being made of chrome on the surface of the base material at a first deposition speed by sputtering;
a second deposition process depositing a second chrome film being made of chrome on a surface of the first chrome film at a second deposition speed that is higher than the first deposition speed by sputtering; and
a crack forming process forming a crack within the first chrome film and within the second chrome film by an application of a stress to the first chrome film and to the second chrome film.

2. The manufacturing method of the metallic film according to claim 1, wherein
the first deposition speed corresponds to a deposition speed which is low to an extent where the first chrome film includes an adhesive strength which is to an extent where the first chrome film is not removed from the base material, the first deposition speed corresponding to the deposition speed which is low to an extent where the first chrome film has an enhanced specularity; and
the second deposition speed corresponds to a deposition speed which is high to an extent where the second chrome film has a brightness that is equal to or greater than a predetermined brightness.

3. The manufacturing process of the metallic film according to claim 1, wherein
the first deposition speed corresponds to a deposition speed which is low to an extent where an internal stress generated within the first chrome film is equal to or less than a predetermined internal stress; and
the second deposition speed corresponds to a deposition speed which is high to an extent where the brightness of the second chrome film is equal to a brightness of a decorative chrome plating film.

4. The manufacturing process of the metallic film according to claim 1, wherein
the first deposition speed is equal to or less than 0.6 nanometer per second; and
the second deposition speed is equal to or greater than 1.2 nanometer per second.

5. The manufacturing process of the metallic film according to claim 1, wherein
a total film thickness serving as a sum of a film thickness of the first chrome film deposited in the first deposition process and a film thickness of the second chrome film deposited in the second deposition process is equal to or greater than 30 nanometer.

6. The manufacturing process of the metallic film according to claim 5, wherein
the total film thickness is equal to or greater than 50 nanometer.

7. The manufacturing process of the metallic film according to claim 1, wherein
the film thickness of the second chrome film being deposited in the second deposition process is greater than the film thickness of the first chrome film being deposited in the first deposition process.

8. The manufacturing process of the metallic film according to claim 7, wherein
a ratio R (T2/T1) of the film thickness T2 of the second chrome film relative to the film thickness T1 of the first chrome film is equal to or greater than 5 and is equal to or less than 9.

9. An outside door handle for a vehicle, the outside door handle including electrical insulation properties and a radio wave permeability, comprising:
a non-electric conductive handle body being mounted on an outer surface of a door of the vehicle;
a first chrome film being made of chrome, the first chrome film being deposited on a surface of the handle body at a first deposition speed by sputtering; and
a second chrome film being made of chrome, the second chrome film being deposited on a surface of the first chrome film at a second speed that is higher than the first deposition speed; wherein
a crack is formed within the first chrome film and within the second chrome film.

10. The outside door handle for the vehicle according to claim 9, wherein
the first deposition speed corresponds to a deposition speed which is low to an extent where the first chrome film includes an adhesive strength which is to an extent where the first chrome film is not removed from the base material, the first deposition speed corresponding to the deposition speed which is low to an extent where the first chrome film has an enhanced specularity; and
the second deposition speed corresponds to a deposition speed which is high to an extent where the second chrome film has a brightness that is equal to or greater than a predetermined brightness.

11. The outside door handle for the vehicle according to claim 9, wherein
the first deposition speed corresponds to a deposition speed which is low to an extent where an internal stress generated within the first chrome film is equal to or less than a predetermined internal stress; and
the second deposition speed corresponds to a deposition speed which is high to an extent where the brightness of the second chrome film is equal to a brightness of a decorative chrome plating film.

12. The outside door handle for the vehicle according to claim 9, wherein
the first deposition speed is equal to or less than 0.6 nanometer per second; and
the second deposition speed is equal to or greater than 1.2 nanometer per second.

13. The outside door handle for the vehicle according to claim 9, wherein
a total film thickness serving as a sum of a film thickness of the first chrome film and a film thickness of the second chrome film is equal to or greater than 30 nanometer.

14. The outside door handle for the vehicle according to claim 13, wherein
the total film thickness is equal to or greater than 50 nanometer.

15. The outside door handle for the vehicle according to claim 9, wherein
the film thickness of the second chrome film is greater than the film thickness of the first chrome film.

16. The outside door handle for the vehicle according to claim 15, wherein
a ratio R (T2/T1) of the film thickness T2 of the second chrome film relative to the film thickness T1 of the first chrome film is equal to or greater than 5 and is equal to or less than 9.
